(19) United States
(12) Patent Application Publication
(10) Pub. No.: US 2026/0058091 A1
(43) Pub. Date: Feb. 26, 2026

(54) SYSTEM, DEVICE AND METHOD OF CONTROLLING EMISSION CURRENT OF ELECTRON MICROSCOPE

(71) Applicant: Samsung Electronics Co., Ltd., Suwon-si (KR)

(72) Inventors: Jinwoo LEE, Suwon-si (KR); Bumjoo LEE, Suwon-si (KR); Doyeon KIM, Suwon-si (KR); HONGCHE NOH, Suwon-si (KR); SUNGHOON PARK, Suwon-si (KR); JONGCHEON SUN, Suwon-si (KR); SUYOUNG LEE, Suwon-si (KR)

(21) Appl. No.: 19/070,670

(22) Filed: Mar. 5, 2025

(30) Foreign Application Priority Data
Aug. 22, 2024 (KR) 10-2024-0112958

(51) Int. Cl. H01J 37/24; H01J 37/28

(52) U.S. Cl. CPC H01J 37/243; H01J 37/28

(57) ABSTRACT

Disclosed is an electron microscope system including a light generator including a modulator that modulates excitation light based on a control signal, an electron gun including a photocathode that generates an emission current as the modulated excitation light is radiated on the photocathode, wherein an amount of the generated emission current depends on the modulated excitation light, a sensor circuit that senses the emission current as the emission current is generated, and a control unit that generates the control signal based on an amount of a reference current and an amount of the sensed emission current.

### CROSS-REFERENCE TO RELATED APPLICATIONS

This application claims priority under 35 U.S.C. § 119 to Korean Patent Application No. 10-2024-0112958 filed on Aug. 22, 2024, in the Korean Intellectual Property Office, the disclosures of which are incorporated by reference herein in their entireties.

### BACKGROUND

The present disclosure relates to electron microscopes.

Semiconductor elements may be manufactured through a variety of processes. During a testing process among various processes, the performance of semiconductor elements (e.g., a semiconductor element substrate, a semiconductor element in the form of a wafer, or other semiconductor elements) may be tested, for example to determine whether they are functional or defective. A variety of equipment may be used to test the semiconductor elements. For example, a scanning electron microscope (SEM) may be used to test the semiconductor elements.

The SEM may utilize secondary electrons and/or backscattered electrons generated from a specimen by emitting an electron beam onto the specimen. Among various methods in which the SEM generates an electron beam, a photocathode method may generate an electron beam by using the photoelectric effect that occurs in a photocathode.

When the photoelectric effect occurs in the photocathode, an emission current may be generated together with an electron beam. To improve the performance of the SEM, it is useful to provide control over the characteristics of the electron beam and emission current.

### SUMMARY

Embodiments of the present disclosure provide a system, a device, and a method for controlling an emission current of an electron microscope in real time without adding a separate configuration within a column of an electron microscope and without energy loss.

According to an embodiment, an electron microscope system includes a light source unit including a modulator that modulates excitation light based on a control signal, an electron gun including a photocathode that generates an emission current as the modulated excitation light is radiated on the photocathode, wherein an amount of the generated emission current depends on the modulated excitation light, a sensor circuit that senses the emission current as the emission current is generated, and a control unit that generates the control signal based on an amount of a reference current and an amount of the sensed emission current.

According to an embodiment, an emission current controlling method of an electron microscope includes radiating excitation light to a photocathode included in an electron gun, generating, by the photocathode, an emission current based on the radiated excitation light, sensing the emission current while the emission current is generated, generating a control signal based on an amount of a reference current and an amount of the sensed emission current, and modulating the excitation light based on the control signal, wherein an amount of the emission current depends on the modulated excitation light.

According to an embodiment, an electron microscope system includes a light generator including a light source that irradiates excitation light, and a modulator that modulates the excitation light based on a control signal, a scanning electron microscope (SEM) column unit including an electron gun and a beam generation space, the electron gun including a photocathode that generates an emission current and an electron beam based on the excitation light, wherein an amount of the generated emission current depends on the modulated excitation light, and that emits the electron beam, and the beam generation space that emits the electron beam onto a specimen and detects a secondary electron emitted from the specimen in response to the electron beam, and a feedback circuit including a sensor circuit that senses the emission current at the same time that the secondary electron is emitted from the specimen and a control unit that generates the control signal based on an amount of a reference current and an amount of the sensed emission current, and transmits the control signal to the light generator.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating an electron microscope system for monitoring an emission current of an electron microscope.

FIG. 2 is a block diagram illustrating an electron gun of an electron microscope system for monitoring an emission current of an electron microscope.

FIG. 3 is a block diagram illustrating an electron microscope system that controls the emission current of an electron microscope, according to an embodiment of the present disclosure.

FIG. 4 is a flowchart illustrating an example of a method of operating an electron microscope system that controls an emission current of an electron microscope, according to an embodiment of the present disclosure.

FIG. 5 is a block diagram illustrating a light source unit, according to an embodiment of the present disclosure.

FIG. 6 is a flowchart illustrating an example of a method of operating a light source unit, according to an embodiment of the present disclosure.

FIG. 7 is a block diagram illustrating an electron gun, according to an embodiment of the present disclosure.

FIG. 8 is a block diagram illustrating a beam generation space, according to an embodiment of the present disclosure.

FIG. 9 is a circuit diagram illustrating a feedback path for controlling an emission current of an electron microscope, according to an embodiment of the present disclosure.

FIG. 10 is a flowchart illustrating an example of a method of operating a sensor circuit, according to an embodiment of the present disclosure.

FIG. 11 is a flowchart illustrating an example of a method of operating a control unit, according to an embodiment of the present disclosure.

### DETAILED DESCRIPTION

Hereinafter, embodiments of the present disclosure may be described in detail and clearly to such an extent that a person of ordinary skill in the art easily implements the present disclosure. Embodiments of the present disclosure described herein relate to an electron microscope, and more particularly, relate to a system, device, and method for controlling the emission current of an electron microscope in real time (e.g., while the emission current is generated, and/or at the same time as using the electron microscope for imaging). The disclosed embodiments can provide a SEM with improved performance, in which the intensity of the electron beam and the amount of the emission current are stably maintained within a specific range.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

As used herein, a semiconductor element or semiconductor device may refer, for example, to a device such as a semiconductor chip (e.g., memory chip and/or logic chip formed on a die), a stack of semiconductor chips, a semiconductor package including one or more semiconductor chips stacked on a package substrate, a package-on-package device including a plurality of packages, or a part or portion thereof. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

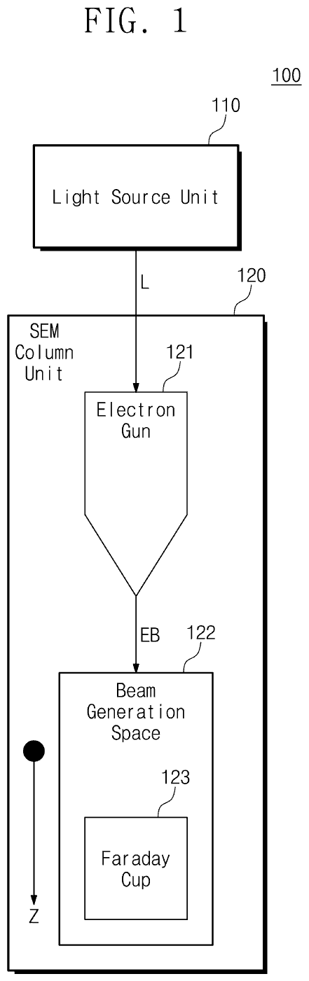

FIG. 1 is a block diagram illustrating an electron microscope system for monitoring an emission current of an electron microscope. Referring to FIG. 1, an electron microscope system 100 may include a light source unit 110 (also referred to herein as a light generator 110) and a SEM column unit 120.

The light source unit (e.g., light generator) 110 may radiate excitation light “L” onto the SEM column unit 120. For example, the light source unit 110 may radiate the excitation light “L” implemented as laser light to the SEM column unit 120.

The SEM column unit 120 may include an electron gun 121 and a beam generation space 122. The SEM column unit 120 may generate an electron beam EB based on the excitation light “L” radiated from the light source unit 110. The interior of the SEM column unit 120 may be maintained in a vacuum state. For example, a vacuum pump (not shown) for maintaining the interior of the SEM column unit 120 in a vacuum state may be connected to the SEM column unit 120.

Hereinafter, a direction in which the generated electron beam EB propagates within the SEM column unit 120 is defined as a “Z” direction. For example, the “Z” direction may be a vertical downward direction. Although the “Z” direction in the present disclosure is described as a vertically downward direction, this is an example and the present disclosure is not limited thereto.

The electron gun 121 may include a photocathode. When the excitation light “L” is radiated onto the photocathode, a photoelectric effect may occur in the photocathode. As the photoelectric effect occurs in the photocathode, electrons may be emitted from the photocathode. The electron gun 121 may generate the electron beam EB by accelerating the emitted electrons. The electron gun 121 may emit the generated electron beam EB into the beam generation space 122.

A specimen (e.g., a semiconductor element, etc.) to be tested (e.g. examined) by the electron microscope system 100 may be located in the beam generation space 122. The electron beam EB may be formed along the “Z” direction within the beam generation space 122, and accordingly may be emitted onto the specimen. For example, the specimen may be placed in a path of the formed electron beam EB. A user may test a specimen based on secondary electrons emitted from the specimen as the electron beam EB is emitted onto the specimen.

In addition, a Faraday cup 123 may be located in the beam generation space 122. For example, when the current (e.g., emission current) of the electron beam EB is to be measured (or monitored), the user may place the Faraday cup 123 within the beam generation space 122.

For example, when the current of the electron beam EB is to be measured, the user may place the Faraday cup 123 in the beam generation space 122 to be spaced apart from the specimen in a negative “Z” direction (e.g., in the opposite direction to the “Z” direction, or closer to the electron gun 121). In this case, the electron beam EB from the electron gun 121 may be emitted onto the Faraday cup 123. As the electron beam EB is emitted onto the Faraday cup 123, the Faraday cup 123 may measure the current of the electron beam EB.

Moreover, in this example, the electron beam EB may not be emitted onto a specimen placed to be spaced apart from the Faraday cup 123 in the “Z” direction. For example, as the Faraday cup 123 is spaced apart from the specimen in the negative “Z” direction, or closer to the electron gun 121, the Faraday cup 123 may block the electron beam EB emitted onto the specimen. Accordingly, the user may not test the specimen.

For another example, when the current of the electron beam EB is measured, the user may remove the specimen from the beam generation space 122 and may place the Faraday cup 123 on the path of the electron beam EB. In this case, the electron beam EB emitted from the electron gun 121 may be emitted onto the Faraday cup 123. As the electron beam EB is emitted onto the Faraday cup 123, the Faraday cup 123 may measure the current of the electron beam EB. Furthermore, because the specimen is removed from the beam generation space 122, the user may not test the specimen.

The electron microscope system 100 may not measure the current of the electron beam EB in real time while also testing a specimen (e.g., at the same time as testing or imaging the specimen). In addition, in a process of changing the placement of each of the specimen and the Faraday cup 123 within the SEM column unit 120 maintained in a vacuum state, the electric potential, a temperature, or the like formed within the SEM column unit 120 may change, and the amount of the emission current may change.

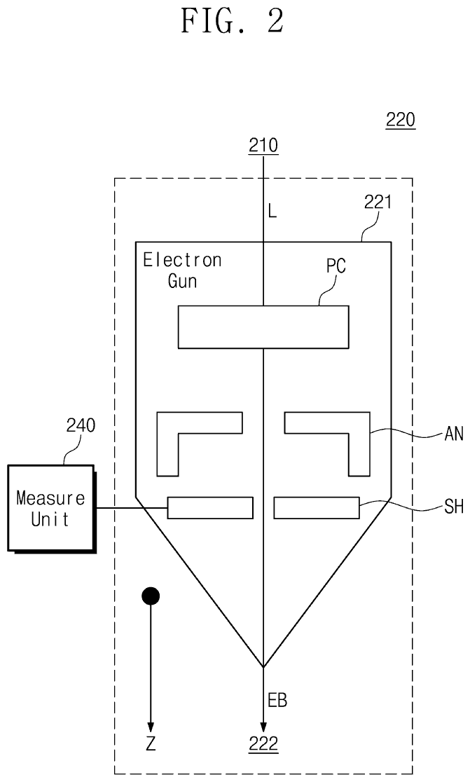

FIG. 2 is a block diagram illustrating an electron gun of a second electron microscope system for monitoring an emission current of an electron microscope. Referring to FIG. 2, an electron gun 221 may include a photocathode PC, an anode AN, and a shield SH.

The electron gun 221 may emit the electron beam EB into a beam generation space 222 based on the excitation light “L” radiated from a light source unit 210. A measure unit 240 may be connected to the shield SH of the electron gun 221. For example, the measure unit 240 may be implemented outside a SEM column unit 220 including the electron gun 221.

The photocathode PC may receive the excitation light “L” from the light source unit 210. As the excitation light “L” is radiated on the photocathode PC, a photoelectric effect occurs in the photocathode PC, and electrons may be emitted from the photocathode PC.

The anode AN may generate the electron beam EB by accelerating the emitted electrons. For example, the anode AN may be spaced apart from the photocathode PC in the “Z” direction. The generated electron beam EB may propagate in the “Z” direction.

The shield SH may shield a part of the electron beam EB. The shield SH may be placed to be spaced apart from the anode AN in the “Z” direction. A portion of the electron beam EB propagating in the “Z” direction is shielded by the shield SH, and another portion thereof may pass through the shield SH.

In an example, the shield SH may function to attenuate the electron beam EB as well as to facilitate measuring the attenuated electron beam. For example, the measure unit 240 may measure the portion of the electron beam EB shielded by the shield SH (e.g., a portion of the electron beam that irradiates the shield SH). For example, the measure unit 240 is implemented outside the SEM column unit 220 and may measure a current (e.g., an emission current) of the electron beam EB based on a portion of the electron beam EB shielded by the shield SH. For example, the measure unit 240 may measure the current of the electron beam EB based on the ratio of the portion of the electron beam EB shielded by the shield SH to the total electron beam EB and amount of the electron beam EB shielded by the shield SH.

In the electron microscope system of FIG. 2, energy loss of the electron beam EB may occur in a process of measuring the current (e.g., the emission current) of the electron beam EB. For example, when the current of the electron beam EB is measured, another part of the electron beam EB that is not shielded by the shield SH may be emitted onto the specimen. Accordingly, the energy loss of the electron beam EB corresponding to a portion of the electron beam EB shielded by the shield SH may occur.

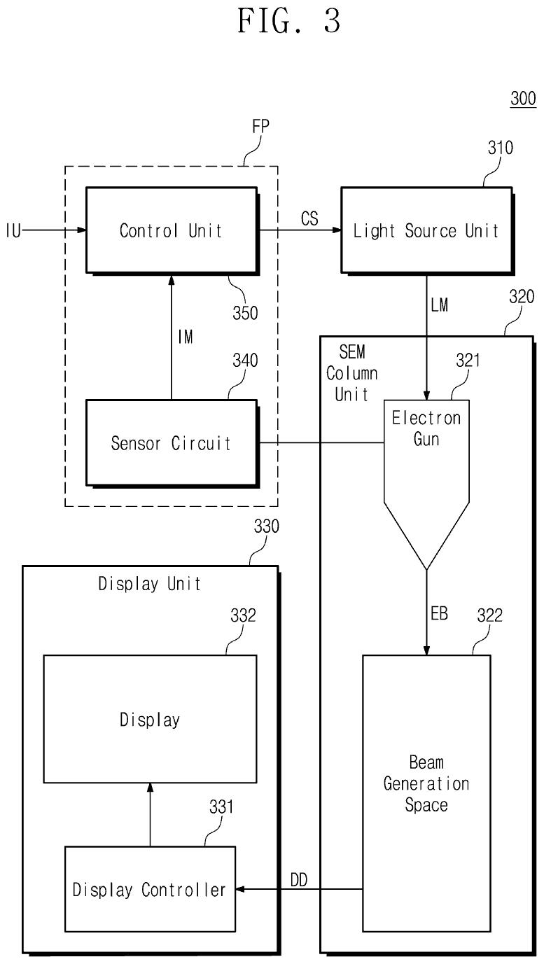

FIG. 3 is a block diagram illustrating an electron microscope system that controls the emission current of an electron microscope, according to an embodiment of the present disclosure. Referring to FIG. 3, an electron microscope system 300 may include a light source unit 310, a SEM column unit 320, a display unit 330, a sensor circuit (also referred to herein as a sensor unit) 340, and a control unit 350.

The light source unit 310, which may also be referred to as a light generator 310 or a light source structure 310, may receive a control signal CS from the control unit 350. The light source unit (e.g., light generator) 310 may radiate modulated excitation light LM to the SEM column unit 320 based on the received control signal CS. For example, the light source unit 310 may include at least one light source element and at least one light modulation element. The at least one light modulation element may modulate initial excitation light, which is radiated by the at least one light source element, into the modulated excitation light LM based on the control signal CS. For example, the at least one light modulation element may modulate the initial excitation light into the modulated excitation light LM by adjusting at least one of the intensity, wavelength, frequency, or polarization state of the initial excitation light based on the control signal CS. Accordingly, the light source unit 310 may radiate the modulated excitation light LM, which is modulated by the at least one light modulation element, to the SEM column unit 320.

The SEM column unit 320 (also referred to herein as a SEM column 320, SEM chamber 320, or SEM housing 320) may generate the electron beam EB based on the modulated excitation light LM, and may generate detected data DD based on the generated electron beam EB. Moreover, the SEM column unit 320 may transmit the detected data DD thus generated to the display unit 330. Hereinafter, a direction in which the generated electron beam EB propagates within the SEM column unit 320 is defined as a “Z” direction. For example, the “Z” direction may be a vertical downward direction. Although the “Z” direction in the present disclosure is described as a vertically downward direction, this is an example and the present disclosure is not limited thereto. The SEM column unit 320 may include an electron gun 321 and a beam generation space 322. In some examples, SEM column unit 320 can be maintained in a vacuum state, and may include a chamber or an external housing.

For example, the electron gun 321 of SEM column unit 320 may generate the electron beam EB based on the modulated excitation light LM. Furthermore, the electron gun 321 may emit the generated electron beam EB into the beam generation space 322. In the present disclosure, the electron gun 321 may be the electron gun 321 based on a photocathode method. Accordingly, the electron gun 321 may include a photocathode. In particular, the photocathode may be configured such that a photoelectric effect occurs in the photocathode as the modulated excitation light LM is radiated thereon.

As the photoelectric effect occurs in the photocathode, electrons may be emitted from the photocathode, and an emission current may be generated from the photocathode. Here, an amount IM of the emission current from the photocathode may be proportional to the number of electrons emitted from the photocathode per unit time (e.g. rate of electrons emitted from the photocathode per unit time). For example, as the intensity of the modulated excitation light LM radiated to the photocathode is strong, the rate of electrons emitted from the photocathode may increase, and the amount IM of the emission current generated from the photocathode may increase. For another example, as the intensity of the modulated excitation light LM radiated to the photocathode is weak, the rate of electrons emitted from the photocathode may decrease, and the amount IM of the emission current generated from the photocathode may decrease.

The electron gun 321 may generate the electron beam EB based on the electrons emitted by the photoelectric effect. For example, the electron gun 321 may emit the electron beam EB into the beam generation space 322 by accelerating the emitted electrons.

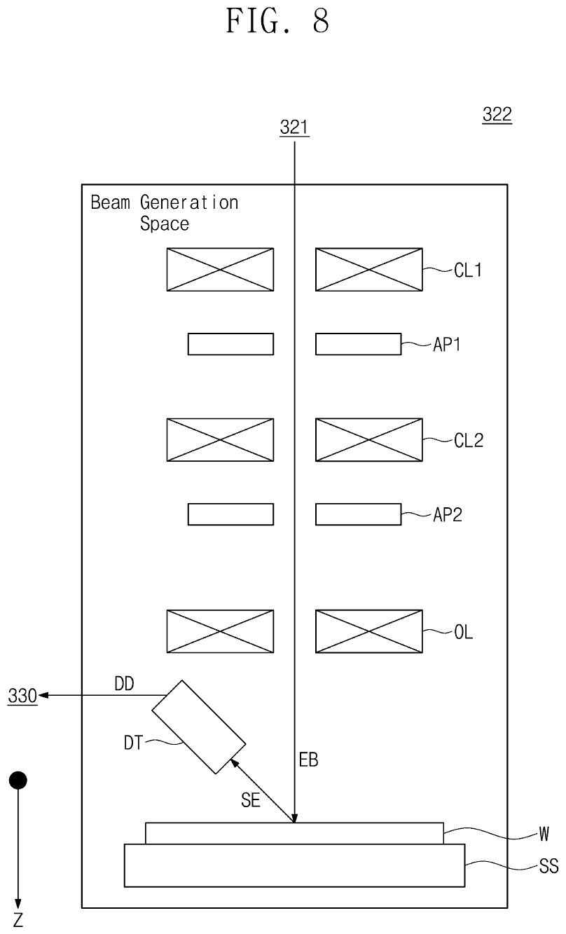

The electron beam EB emitted from the electron gun 321 may be formed within the beam generation space 322. The beam generation space 322 may include a specimen (e.g., a semiconductor element substrate) to be tested (e.g. examined) by the electron microscope system 300. The electron beam EB may be formed in the “Z” direction within the beam generation space 322 and may be emitted onto the specimen. The specimen may be configured such that secondary electrons are emitted as the electron beam EB is emitted. The beam generation space 322 may detect the emitted secondary electrons (e.g., by a detector DT, as described in the example of FIG. 8) and may generate the detected data DD based on the detected secondary electrons. The detected data DD may include information related to the detected secondary electrons.

In some examples, the beam generation space 322 may include a beam generation region (e.g., including the first and second condenser lenses CL1 and CL2, first and second apertures AP1 and AP2, and objective lens OL, as described in the example of FIG. 8), a specimen mounting region, and/or a detection region.

The display unit 330 may receive the detected data DD from the SEM column unit 320 and may output an image based on the received detected data DD. For example, the display unit 330 may include a display controller 331 and a display 332. The display controller 331 may receive the detected data DD from the SEM column unit 320 and may control the display 332 based on the received detected data DD. For example, the display controller 331 may generate an image based on the detected data DD. The display 332 may output the image generated by the display controller 331. A user may determine whether a specimen (e.g., a semiconductor element substrate) is defective, based on the image displayed on the display 332.

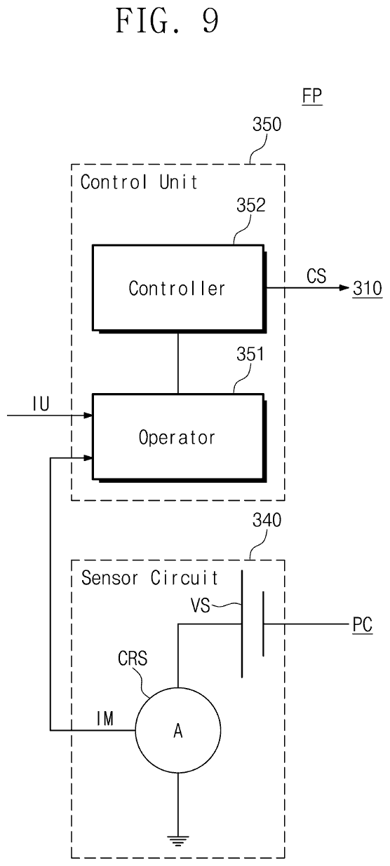

The disclosed electron microscope system 300 may include a feedback path FP configured to include the sensor circuit (e.g., sensor unit) 340 and the control unit 350. The feedback path FP may be implemented outside the SEM column unit 320. The sensor circuit 340 may detect the emission current from the SEM column unit 320. For example, the sensor circuit 340 may detect the emission current generated from the photocathode PC included in the electron gun 321 of the SEM column unit 320. The sensor circuit 340 may include a ground terminal. A supply current having an amount the same as the amount of the emission current may flow between the ground terminal and the photocathode PC, thereby replenishing the photocathode PC. A more detailed example embodiment of this feedback path is described below in FIG. 9. The sensor circuit 340 may detect the emission current by measuring the amount of supply current outside the SEM column unit 320. The sensor circuit 340 may transmit information representing the amount IM of the emission current to the control unit 350 based on the measured amount of the supply current. For example, the determined amount IM of emission current may be equal to the measured amount of the supply current (e.g., the measured amount of the supply current may represent the actual amount of the emission current).

In some examples, the amount of the supply current flowing between the ground terminal and the photocathode PC may be approximately equal to the amount of the emission current. For example, in a case where the supply current supplies one or more other currents in the electron microscope system 300 (for example, to power drains in the sensor circuit 340, control unit 350, and/or other components), the amount of the supply current may equal the sum of the amount of the emission current and the amounts of these one or more other currents. Alternatively or additionally, the amount of the supply current may be substantially equal to the amount of the emission current.

The control unit 350 may receive the amount IM of the emission current detected from the sensor circuit 340 and may receive an amount IU of the reference current, which is set by the user, from the user. For example, the amount IU of the reference current may function as a target amount for the emission current. Moreover, the control unit 350 may generate the control signal CS based on the amount IM of the emission current and the amount IU of the reference current and may transmit (e.g., feed back) the generated control signal CS to the light source unit 310. For example, the control unit 350 may generate the control signal CS based on a difference value between the amount IM of the emission current and the amount IU of the reference current. As described above, the light source unit 310 may modulate initial excitation light into the modulated excitation light LM based on the control signal CS thus received (e.g., fed back).

For example, when the amount IM of the emission current is greater than the amount IU of the reference current, the light source unit 310 may modulate the initial excitation light to decrease the amount IM of the emission current, based on the control signal CS. For another example, when the amount IM of the emission current is smaller than the amount IU of the reference current, the light source unit 310 may modulate the initial excitation light to increase the amount IM of the emission current, based on the control signal CS. For example, the light source unit 310 may modulate the initial excitation light such that the difference value between the amount IM of the emission current and the amount IU of the reference current decreases (e.g., in absolute value), based on the control signal CS.

As described above, the feedback path FP may be implemented outside the SEM column unit 320 and may maintain the amount IM of the emission current generated from the electron gun 321 of the electron microscope within a specific range (for example, about the amount IU of the reference current). The electron microscope system 300 may control the emission current without adding a separate configuration (e.g., a configuration for shielding the electron beam EB, etc.) within the SEM column unit 320. The electron microscope system 300 may not add the separate configuration within the SEM column unit 320, and thus may control the emission current without the loss of the emission current and/or energy of the electron beam EB, as described in the examples of FIGS. 1-2.

Furthermore, the feedback path FP may detect the emission current generated from the photocathode PC included in the electron gun 321 of the SEM column unit 320, and thus may maintain the amount IM of the emission current within a specific range (e.g., about the amount IU) regardless of whether there is a specimen within the beam generation space 322 of the SEM column unit 320. In other words, the disclosed electron microscope system 300 may control the emission current in real time (e.g., while the emission current is generated) regardless of whether the specimen is present within the SEM column unit 320.

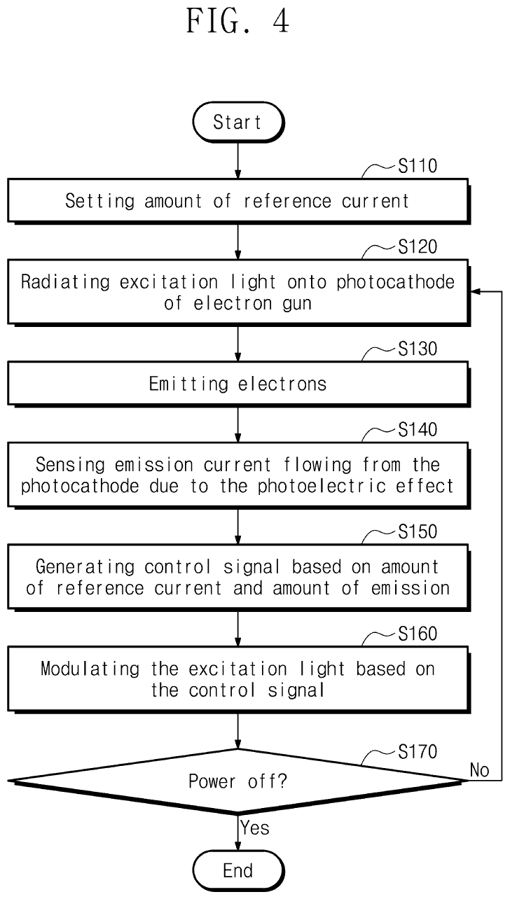

FIG. 4 is a flowchart illustrating an example of a method of operating an electron microscope system that controls an emission current of an electron microscope, according to an embodiment of the present disclosure. Referring to FIGS. 3 and 4, in operation S110, the electron microscope system 300 may set an amount IU of a reference current. For example, the amount IU of the reference current may be set by a user input (e.g., by control logic) or may be received from an external device (e.g., received and stored in the control logic).

In operation S120, the electron microscope system 300 may radiate excitation light onto the photocathode PC of the electron gun 321. For example, the excitation light may be radiated onto the photocathode PC by at least one light source element of the light source unit 310, such as a laser light source or another light source element.

In operation S130, the electron microscope system 300 may emit electrons. For example, the photocathode PC may emit electrons based on the photoelectric effect occurring in the photocathode PC. Here, the photoelectric effect may occur in the photocathode PC as the excitation light is radiated onto the photocathode PC.

In operation S140, the electron microscope system 300 may detect an emission current flowing from the photocathode PC due to the photoelectric effect. For example, the sensor circuit 340 may detect the emission current by measuring the amount of the supply current flowing between the ground terminal and the photocathode PC, which is the same as the amount of the emission current. Alternatively or additionally, the amount of the supply current flowing between the ground terminal and the photocathode PC may be approximately equal to the amount of the emission current, or may be equal to a sum of the amount of the emission current and amounts of any other currents fed by the supply current.

In operation S150, the electron microscope system 300 may generate the control signal CS based on the amount of the reference signal and the amount IM of the emission current. For example, the control unit 350 may generate the control signal CS based on a difference value between the amount of the reference signal and the amount IM of the emission current, and may transmit (e.g., feed back) the control signal CS to the light source unit 310. For example, the control signal CS may be proportional to the difference value between the amount of the reference signal and the amount IM of the emission current. In some examples, the control signal CS may have the opposite sign to the difference value.

In operation S160, the electron microscope system 300 may modulate the excitation light based on the control signal CS. For example, at least one light modulation element of the light source unit 310 may modulate the excitation light, which is radiated by at least one light source element, based on the control signal CS.

In operation S170, it is possible to determine whether a power supply to the electron microscope system 300 is cut off. Responsive to the power supply to the electron microscope system 300 being cut off, the electron microscope system 300 may terminate the operation. Responsive to the power supply to the electron microscope system 300 not being cut off, the electron microscope system 300 may return to operation S120 and may repeat the above-described process.

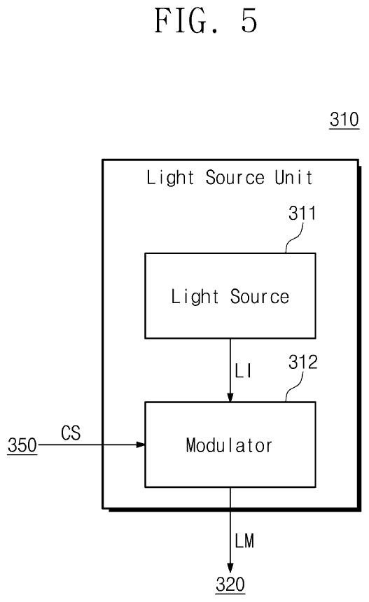

FIG. 5 is a block diagram illustrating a light source unit, according to an embodiment of the present disclosure. Referring to FIGS. 3 and 5, the light source unit 310 may include a light source 311 (also referred to as a light generator 311) and a modulator 312.

The light source unit 310 may receive the control signal CS from the control unit 350 and may radiate the modulated excitation light LM onto the SEM column unit 320. The light source unit 310 may include at least one light source element, which may include the light source 311. The light source unit 310 may also include at least one light modulation element, which may include the modulator 312, such as an electro-optic modulator.

The light source (e.g., light generator) 311 may radiate an initial excitation light LI onto the modulator 312. The light source 311, which radiates the initial excitation light LI, may be a laser light source (e.g., a laser). For example, the light source 311 may be implemented as one of a pulse laser light source (e.g., a pulse laser), a continuous wave laser light source (e.g., a continuous wave laser), a Ti-sapphire laser light source (e.g., a Ti-sapphire laser), and a neodymium-doped yttrium aluminum garnet (ND-YAG) laser light source (e.g., a ND-YAG laser), but this is an example and the present disclosure is not limited thereto.

The modulator 312 may receive the control signal CS from the control unit 350 and may receive the initial excitation light LI from the light source 311. The modulator 312 may modulate the initial excitation light LI (e.g., by electro-optic modulation) to produce the modulated excitation light LM based on the control signal CS. As described above with reference to FIG. 3, the modulator 312 may modulate the initial excitation light LI into the modulated excitation light LM by adjusting at least one of the intensity, wavelength, frequency, or polarization state of the initial excitation light LI based on the control signal CS, but this is an example and the present disclosure is not limited thereto.

For example, when the amount IM of the emission current is greater than the amount IU of the reference current, the modulator 312 may modulate the initial excitation light LI into the modulated excitation light LM by performing at least one of decreasing the intensity of the initial excitation light LI, increasing the wavelength, or decreasing the frequency, based on the control signal CS.

For another example, when the amount IM of the emission current is smaller than the amount IU of the reference current, the modulator 312 may modulate the initial excitation light LI into the modulated excitation light LM by performing at least one of increasing the intensity of the initial excitation light LI, decreasing the wavelength, or increasing the frequency, based on the control signal CS.

In the meantime, depending on the material comprising the photocathode PC and/or its configuration, the efficiency of the photoelectric effect by excitation light in a specific polarization state may be higher than the efficiency of the photoelectric effect by excitation light in a different polarization state. Accordingly, for example, to reduce the difference value between the amount IM of the emission current and the amount IU of the reference current, the modulator 312 may modulate the initial excitation light LI into the modulated excitation light LM by adjusting the polarization state of the initial excitation light LI, based on the control signal CS. This adjustment of the polarization state may, in turn, affect the efficiency of the photoelectric effect in photocathode PC, which may result in the amount IM of the emission current approaching the amount IU of the reference current.

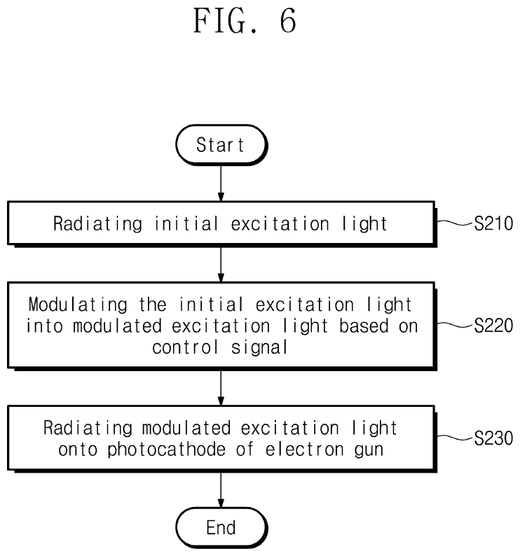

FIG. 6 is a flowchart illustrating an example of a method of operating the light source unit 310, according to an embodiment of the present disclosure. Referring to FIGS. 5 and 6, in operation S210, the light source unit 310 may radiate the initial excitation light LI. For example, the light source 311 may radiate the initial excitation light LI, which may be implemented as laser light, onto the modulator 312.

In operation S220, the light source unit 310 may modulate the initial excitation light LI to the modulated excitation light LM based on the control signal CS. For example, the modulator 312 may receive the control signal CS from the control unit 350 and may modulate the initial excitation light LI into the modulated excitation light LM based on the received control signal CS.

In operation S230, the light source unit 310 may radiate the modulated excitation light LM to the photocathode PC of the electron gun 321. For example, the modulator 312 may induce a photoelectric effect in the photocathode PC by radiating the modulated excitation light LM to the photocathode PC.

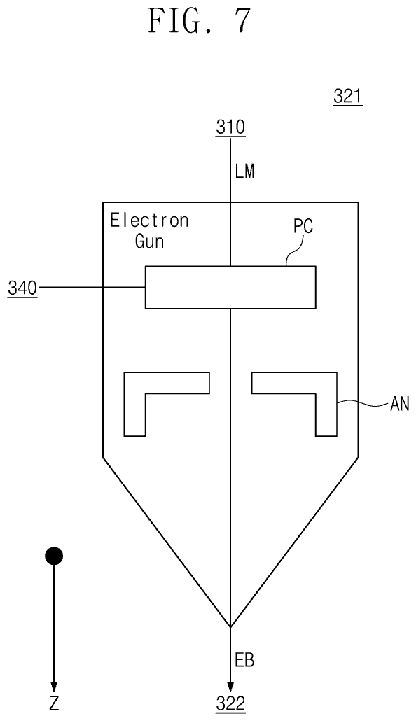

FIG. 7 is a block diagram illustrating an electron gun, according to an embodiment of the present disclosure. Referring to FIGS. 3 and 7, the electron gun 321 may include the photocathode PC and the anode AN.

The electron gun 321 may receive the modulated excitation light LM from the light source unit 310, may generate the electron beam EB based on the received modulated excitation light LM, and may emit the generated electron beam EB into the beam generation space 322.

The photocathode PC may generate the electron beam EB based on the modulated excitation light LM radiated by the light source unit 310. For example, when the modulated excitation light LM is radiated on the photocathode PC, a photoelectric effect occurs in the photocathode PC, and an emission current may be generated by the photoelectric effect. Hereinafter, descriptions, which are the same as the descriptions above with reference to FIG. 3 in the detailed description of the photocathode PC, are omitted. The material forming the photocathode PC may be a material capable of generating the photoelectric effect as the modulated excitation light LM is radiated. The emission current may be detected by the sensor circuit 340.

The anode AN may accelerate electrons emitted by the photoelectric effect from the photocathode PC. For example, the emitted electrons may be accelerated by the electric field formed by the photocathode PC and the anode AN. The electron beam EB may be generated by accelerating the emitted electrons. As described above with reference to FIG. 3, a direction in which the electron beam EB propagates is defined as the “Z” direction. For example, the anode AN may be spaced apart from the photocathode PC in the “Z” direction.

Each of the photocathode PC and the anode AN may have an electric potential (e.g., a potential). The electric field may be formed between the photocathode PC and the anode AN based on a potential difference between the potential of the photocathode PC and the potential of the anode AN. For example, the potential of the photocathode PC may be lower than the potential of the anode AN. Accordingly, the electron beam EB generated by the electric field may propagate in the “Z” direction.

FIG. 8 is a block diagram illustrating a beam generation space, according to an embodiment of the present disclosure. Referring to FIGS. 3 and 8, the beam generation space 322 may include a first condenser lens CL1, a first aperture AP1, a second condenser lens CL2, a second aperture AP2, an objective lens OL, a specimen stage SS, a specimen “W”, and a detector DT.

The first condenser lens CL1 may focus the electron beam EB into a narrow area. For example, the first condenser lens CL1 may include a cylindrical shape, but this is an example and the present disclosure is not limited thereto. The first condenser lens CL1 may include an electromagnet and/or a capacitor. The first condenser lens CL1 may adjust a direction in which the electron beam EB propagates, based on the Lorentz force applied to the electron beam EB moving in a magnetic field.

The first aperture AP1 may determine the diameter of the electron beam EB emitted through the first condenser lens CL1 and may prevent the scattering of the electron beam EB. As described above with reference to FIG. 3, a direction in which the electron beam EB propagates is defined as the “Z” direction. The first aperture AP1 may be spaced apart from the first condenser lens CL1 along the “Z” direction.

The second condenser lens CL2 may be spaced apart from the first aperture AP1 in the “Z” direction. The second aperture AP2 may be spaced apart from the second condenser lens CL2 in the “Z” direction. The function of the second condenser lens CL2 is the same as that of the first condenser lens CL1, and thus redundant descriptions are omitted. Moreover, the function of the second aperture AP2 is the same as that of the first aperture AP1, and thus redundant descriptions are omitted. Although the beam generation space 322 in the present disclosure is described as including two condenser lenses and two apertures, this is an example and the present disclosure is not limited thereto, and may include any number of condenser lenses and/or apertures.

The objective lens OL may focus the electron beam EB, which passes through the first condenser lens CL1, the first aperture AP1, the second condenser lens CL2, and the second aperture AP2 and is emitted onto the specimen “W”, into a narrow area. For example, the objective lens OL may focus the electron beam EB onto the specimen “W”.

The specimen stage SS may support the specimen “W”. The specimen “W” may be placed on the specimen stage SS. For example, the specimen “W” may be spaced apart from the objective lens OL in the “Z” direction. In an embodiment of the present disclosure, the specimen “W” may be a semiconductor element in the form of a wafer, but this is an example and the present disclosure is not limited thereto. The electron beam EB passing through the objective lens OL may be emitted onto the specimen “W”. As the electron beam EB is emitted onto the specimen “W”, the specimen “W” may emit a secondary electron SE.

The detector DT may be a standard SEM detector that detects secondary electrons and converts them into data for use by a control system. The detector DT may detect the secondary electron SE emitted from the specimen “W”. The detector DT may generate the detected data DD based on the detected secondary electron SE. The detected data DD may include information related to the detected secondary electron SE. The detector DT may transmit the detected data DD to the display unit 330.

FIG. 9 is a circuit diagram illustrating a feedback path for controlling an emission current of an electron microscope, according to an embodiment of the present disclosure. Referring to FIGS. 3 and 9, the feedback path FP may include the sensor circuit 340 and the control unit 350. The feedback path FP may be implemented outside the SEM column unit 320. The electron microscope system 300 may maintain the amount IM of the emission current within a specific range by a real-time feedback operation of the feedback path FP. Hereinafter, descriptions, which are the same as the descriptions above with reference to FIG. 3 in the detailed description of the feedback path FP, are omitted.

The sensor circuit 340 may detect an emission current generated from the photocathode PC and may transmit the amount IM of the detected emission current to the control unit 350. The sensor circuit 340 may include a DC voltage source VS and a current sensor CRS.

The DC voltage source VS may be connected between the photocathode PC and a ground terminal. Referring to FIGS. 7 and 9, the photocathode PC may have an electric potential (e.g., a potential). For example, a value of the DC voltage source VS may be the same as the electric potential of the photocathode PC. The DC voltage source VS may form the electric potential at the photocathode PC.

In the meantime, in FIG. 9, although the DC voltage source VS is illustrated as having a cathode connected to the photocathode PC, this is an example, and the present disclosure is not limited thereto. For example, a connection direction of the DC voltage source VS may vary depending on the electric potential of the photocathode PC set by a user of the electron microscope system 300. For example, when the electric potential of the photocathode PC is set to a negative value, the DC voltage source VS may be connected to a negative electrode of the photocathode PC, as shown in FIG. 9. As another example, when the electric potential of the photocathode PC is set to a positive value, the DC voltage source VS may be connected to a positive electrode of the photocathode PC.

The current sensor CRS may measure a current flowing between the DC voltage source VS and the ground terminal. For example, the current sensor CRS may be connected between the DC voltage source VS and the ground terminal. Referring to FIGS. 3, 7, and 9, the photocathode PC may be configured such that a photoelectric effect occurs in the photocathode PC as the modulated excitation light LM is radiated, and an emission current is generated from the photocathode PC by the photoelectric effect.

Here, as the emission current is generated from the photocathode PC, a supply current may flow from the ground terminal to the photocathode PC. In particular, the amount of the supply current may be the same as (e.g., equal or substantially equal to) the amount IM of the emission current. Therefore, the amount IM of the emission current generated from the photocathode PC may be the same as the amount of the supply current supplied from the ground terminal. Accordingly, the amount of a current (e.g., the supply current) flowing between the DC voltage source VS and the ground terminal, which is measured by the current sensor CRS, may be equal to the amount IM of the emission current generated from the photocathode PC.

Accordingly, the feedback path FP may detect the emission current by measuring the amount of the supply current flowing between the DC voltage source VS and the ground terminal outside the SEM column unit 320. The current sensor CRS of the sensor circuit 340 may transmit information representing the amount IM of the detected emission current to the control unit 350 based on the measured amount of the supply current. Therefore, the current sensor CRS may transmit the amount of the supply current as the amount IM of the emission current to the control unit 350.

The control unit 350 may generate the control signal CS based on the amount IM of the emission current received from the sensor circuit 340 and the amount IU of the reference current received from a user and may transmit the generated control signal CS to the light source unit 310. The control unit 350 may include an operator 351 and a controller 352.

In various embodiments, the control unit 350 may include hardware as well as software, and may be, for example, part of a computer or computer system, and may include one or more integrated circuits formed on one or more semiconductor chips, as well as other circuit components, that are configured to execute computer program code for carrying out the various steps described herein. For example, although not illustrated, the control unit 350, operator 351, and/or controller 352 may include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the control unit 350, operator 351, and/or controller 352 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the control unit 350, operator 351, and/or controller 352 may include antennas, network interfaces that provide wireless and/or wire line digital and/or analog interface to one or more networks over one or more network connections (not shown), a power source that provides an appropriate alternating current (AC) or direct current (DC) to power one or more components of the control unit 350, operator 351, and/or controller 352, and a bus that allows communication among the various disclosed components of the control unit 350, operator 351, and/or controller 352.

The operator 351 (also referred to herein as operator circuitry 351) may receive the amount IM of the emission current from the sensor circuit 340 and may receive the amount IU of the reference current from the user. Moreover, the operator (e.g., operator circuitry) 351 may determine a difference value between the amount IM of the emission current and the amount IU of the reference current. The operator 351 may transmit the determined (e.g., operated) difference value to the controller 352. The operator 351 may be, for example, an automated program, implemented with hardware, such as the hardware described above, and instructions (e.g., computer program code), for example, that performs these tasks.

The controller 352 may generate the control signal CS based on the difference value received from the operator 351. The controller 352 may control the light source unit 310 by transmitting (e.g., feeding back) the generated control signal CS to the light source unit 310. Referring to FIGS. 3, 5, and 9, the modulator 312 may modulate the initial excitation light LI into the modulated excitation light LM based on the control signal CS. As the modulated excitation light LM is radiated, the amount IM of the emission current generated from the photocathode PC may vary.

For example, the difference value between the amount IM of the emission current and the amount IU of the reference current before the controller 352 feeds back the control signal CS to the light source unit 310 may be greater than the difference value between the amount IM of the emission current and the amount IU of the reference current after the controller 352 feeds back the control signal CS to the light source unit 310. Accordingly, the amount IM of the emission current of the electron microscope may be maintained within a specific range (e.g., so as to be similar to the amount IU of the reference current set by the user).

The controller 352 may be implemented based on at least one of conventional controllers such as a proportional-integral-derivative (PID) controller, a lead-lag compensator, a state feedback controller, an optimal controller, and an adaptive controller, but this is an example and the present disclosure is not limited thereto.

When complex control such as robust control is required, the controller 352 may be implemented based on a disturbance observer (DOB). For example, when control for disturbances such as temperature changes within the SEM column is required, the controller 352 may be implemented based on a DOB. In this case, the sensor circuit 340 may further include a temperature sensor for detecting a temperature within a SEM column.

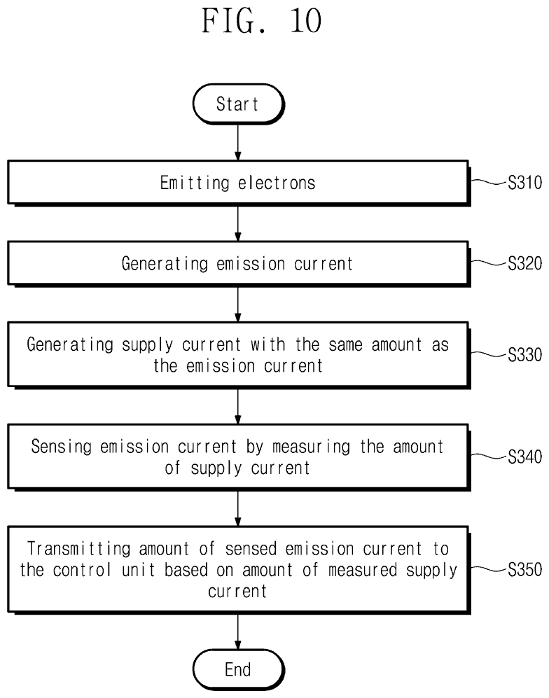

FIG. 10 is a flowchart illustrating an example of a method of operating the sensor circuit 340, according to an embodiment of the present disclosure. Referring to FIGS. 9 and 10, in operation S310, the electron microscope system 300 may emit electrons. For example, the photocathode PC may emit electrons based on the photoelectric effect occurring in the photocathode PC.

In operation S320, the sensor circuit 340 may generate an emission current. For example, the photocathode PC may generate the emission current, of which the amount is proportional to the number of electrons emitted per unit time from the photocathode PC.

In operation S330, the sensor circuit 340 may generate a supply current with the same amount as the emission current. For example, as the emission current is generated from the photocathode PC, the supply current having the same amount as the emission current may flow from the ground terminal to the photocathode PC.

In operation S340, the sensor circuit 340 may sense the emission current by measuring the amount of the supply current. For example, the current sensor CRS may detect the emission current, which has the same amount as the supply current, by measuring the amount of the supply current.

In operation S350, the sensor circuit 340 may transmit information representing the amount IM of the emission current, which is sensed based on the measured amount of the supply current, to the control unit 350. For example, the current sensor CRS may transmit the amount IM of the emission current, which is equal to the measured amount of the supply current, to the control unit 350.

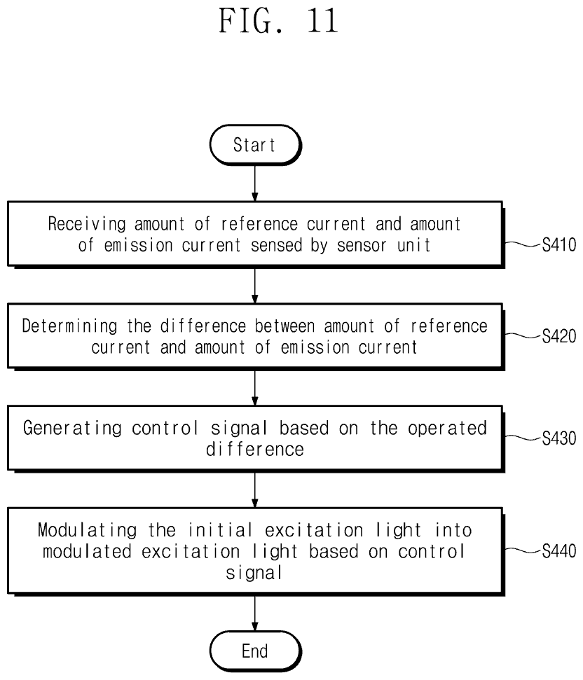

FIG. 11 is a flowchart illustrating an example of a method of operating the control unit 350, according to an embodiment of the present disclosure. Referring to FIGS. 9 and 11, in operation S410, the control unit 350 may receive the amount IU of a reference current and the amount IM of an emission current. For example, the operator 351 may receive the amount IU of the reference current, which is set by a user input (e.g., via control logic) or is received from an external device (e.g., received and stored in the control logic), and the amount IM of the emission current sensed by the sensor circuit 340.

In operation S420, the control unit 350 may determine a difference value between the amount IU of the reference current and the amount IM of the emission current. For example, the operator 351 may determine (e.g., operate) the difference value between the amount IU of the reference current and the amount IM of the emission current.

In operation S430, the control unit 350 may generate the control signal CS based on the determined difference value. For example, the controller 352 may receive the difference value from the operator 351 and may generate the control signal CS based on the received difference value.

In operation S440, the electron microscope system 300 may modulate the initial excitation light LI into the modulated excitation light LM based on the control signal CS. For example, the light source unit 310 (e.g., the modulator 312 of the light source unit 310) may receive the control signal CS from the controller 352, and may modulate the initial excitation light LI into the modulated excitation light LM based on the received control signal CS.

The above description refers to detailed embodiments for carrying out the present disclosure. The present disclosure may include embodiments in which a design is changed simply or which are easily changed, as well as the embodiments described above. In addition, technologies that are easily changed and implemented by using the above embodiments may be included in the present disclosure. While the present disclosure has been described with reference to embodiments described above, it will be apparent to those of ordinary skill in the art that various changes and modifications may be made thereto without departing from the spirit and scope of the present disclosure as set forth in the following claims.

According to embodiments of the present disclosure, it is possible to provide a system, a device and a method for controlling an emission current of an electron microscope, which monitor an emission current generated by a photoelectric effect in a photocathode and maintain the amount of the emission current within a specific range. Accordingly, it is possible to provide a system, a device, and a method for controlling an emission current of an electron microscope in real time without adding a separate configuration within a column of an electron microscope and without energy loss.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. An electron microscope system, the electron microscope system comprising:
a light generator including a modulator configured to modulate excitation light based on a control signal;
an electron gun including a photocathode configured to generate an emission current as the modulated excitation light is radiated on the photocathode, wherein an amount of the generated emission current depends on the modulated excitation light;
a sensor circuit configured to sense the emission current as the emission current is generated; and
a control unit configured to generate the control signal based on an amount of a reference current and an amount of the sensed emission current.

2. The electron microscope system of claim 1, wherein as a result of the modulated excitation light being radiated on the photocathode, a photoelectric effect occurs in the photocathode, and the emission current is generated in the photocathode due to the photoelectric effect.

3. The electron microscope system of claim 2, wherein the sensor circuit includes:
a voltage source connected between the photocathode and a ground terminal; and
a current sensor configured to measure an amount of a supply current flowing between the voltage source and the ground terminal.

4. The electron microscope system of claim 3, wherein the amount of the supply current is equal to the amount of the emission current, and
wherein the current sensor is configured to sense the emission current based on the measured amount of the supply current.

5. The electron microscope system of claim 1, wherein the control unit is configured to:
receive the amount of the reference current as a user input; and
receive the amount of the sensed emission current from the sensor circuit.

6. The electron microscope system of claim 5, wherein the control unit includes:
operator circuitry configured to determine a difference value between the amount of the reference current and the amount of the emission current; and
a controller configured to generate the control signal based on the difference value and to transmit the generated control signal to the light generator.

7. The electron microscope system of claim 1, wherein the light generator further includes a light source configured to radiate the excitation light to the modulator, and
wherein the modulator is configured to modulate the excitation light by adjusting at least one of an intensity, a wavelength, a frequency, or a polarization state of the excitation light based on the control signal.

8. The electron microscope system of claim 7, wherein the modulator is configured to:
responsive to the amount of the emission current being greater than the amount of the reference current, cause the intensity of the excitation light based on the control signal to decrease; and
responsive to the amount of the emission current being smaller than the amount of the reference current, cause the intensity of the excitation light based on the control signal to increase.

9. The electron microscope system of claim 7, wherein the modulator is configured to:
responsive to the emission current being greater than the reference current, cause the wavelength of the excitation light based on the control signal to increase; and
responsive to the emission current being smaller than the reference current, cause the wavelength of the excitation light based on the control signal to decrease.

10. An emission current controlling method of an electron microscope, the method comprising:
radiating excitation light to a photocathode included in an electron gun;
generating, by the photocathode, an emission current based on the radiated excitation light;
sensing the emission current while the emission current is generated;
generating a control signal based on an amount of a reference current and an amount of the sensed emission current; and
modulating the excitation light based on the control signal, wherein an amount of the emission current depends on the modulated excitation light.

11. The method of claim 10, wherein the generating of the emission current further includes:
triggering a photoelectric effect in the photocathode as the excitation light is radiated onto the photocathode; and
generating the emission current from the photocathode due to the photoelectric effect.

12. The method of claim 11, wherein:
a voltage source is connected between the photocathode and a ground terminal;
a current sensor is connected between the voltage source and the ground terminal; and
sensing the emission current is performed by the current sensor.

13. The method of claim 12, wherein the sensing of the emission current includes:
causing a supply current having an amount equal to the amount of the emission current to flow between the voltage source and the ground terminal; and
measuring, by the current sensor, the amount of the supply current.

14. The method of claim 10, wherein the generating of the control signal further includes:
receiving the amount of the reference current as a user input; and
receiving the amount of the sensed emission current.

15. The method of claim 14, wherein the generating of the control signal further includes:
determining, by operator circuitry, a difference value between the amount of the reference current and the amount of the emission current; and
generating, by a controller, the control signal based on the difference value.

16. The method of claim 10, wherein the modulating of the excitation light further includes:
radiating, by a light source, the excitation light to a modulator; and
adjusting, by the modulator, at least one of an intensity, a wavelength, a frequency, or a polarization state of the excitation light based on the control signal.

17. The method of claim 16, wherein the adjusting of the at least one of the intensity, the wavelength, the frequency, or the polarization state of the excitation light further includes:
responsive to the amount of the emission current being greater than the amount of the reference current, causing the intensity of the excitation light based on the control signal to decrease; and
responsive to the amount of the emission current being smaller than the amount of the reference current, causing the intensity of the excitation light based on the control signal to increase.

18. The method of claim 16, wherein the adjusting of the at least one of the intensity, the wavelength, the frequency, or the polarization state of the excitation light further includes:
responsive to the amount of the emission current being greater than the amount of the reference current, causing the wavelength of the excitation light based on the control signal to increase; and
responsive to the amount of the emission current being smaller than the amount of the reference current, causing the wavelength of the excitation light based on the control signal to decrease.

19. An electron microscope system, the electron microscope system comprising:
a light generator including a light source configured to radiate excitation light and a modulator configured to modulate the excitation light based on a control signal;
a scanning electron microscope (SEM) column unit including an electron gun and a beam generation space, the electron gun including a photocathode configured to
generate an emission current and an electron beam based on the excitation light, wherein an amount of the generated emission current depends on the modulated excitation light, and
emit the electron beam, and
the beam generation space configured to emit the electron beam onto a specimen and to detect a secondary electron emitted from the specimen in response to the electron beam; and
a feedback circuit including a sensor circuit configured to sense the emission current at the same time that the secondary electron is emitted from the specimen and a control unit configured to generate the control signal based on an amount of a reference current and an amount of the sensed emission current, and to transmit the control signal to the light generator.

20. The electron microscope system of claim 19, wherein the sensor circuit senses the emission current by measuring an amount of a supply current, which has an amount equal to the emission current, and which flows between a ground terminal and the photocathode, and
wherein the control unit is configured to:
receive the amount of the reference current as a user input;
receive the amount of the emission current sensed from the sensor circuit;
determine a difference value between the amount of the reference current and the amount of the emission current; and
generate the control signal based on the difference value.
